(19) United States
(12) Patent Application Publication
(10) Pub. No.: US 2015/0142349 A1
(43) Pub. Date: May 21, 2015

(54) METHOD FOR DETERMINING A STATE OF ENERGY OF AN ELECTROCHEMICAL ACCUMULATOR, DEVICE, MEDIUM, AND COMPUTER PROGRAM

(71) Applicant: COMMISSARIAT A L'ENERGIE ATOMIQUE ET AUX ENERGIES ALTERNATIVES, Paris (FR)

(72) Inventors: Eric Fernandez, Saint Paul de Varces (FR); Tony Delaplagne, Sainte Marie d'Alloix (FR); Romain Franchi, Grenoble (FR); Kelli Mamadou, Fort de France (FR)

(73) Assignee: COMMISSARIAT A L'ENERGIE ATOMIQUE ET AUX ENERGIES ALTERNATIVES, Paris (FR)

(21) Appl. No.: 14/402,396

(22) PCT Filed: May 24, 2013
(86) PCT No.: PCT/EP2013/060798

§ 371 Date: Nov. 20, 2014

(30) Foreign Application Priority Data
May 24, 2012 (FR) 1254795

(51) Int. Cl. G01R 31/36

(52) U.S. Cl. CPC G01R 31/3606; G01R 31/3648
USPC 702/61

(57) ABSTRACT

The method for estimating a final state of energy SOEf of an electrochemical accumulator is carried out from a set of quadruplets of values relating to operating points of the electrochemical accumulator including power (P), temperature (T), state of energy (SOE) and remaining energy (En). Said method implementing at least one interpolation step.

### TECHNICAL FIELD OF THE INVENTION

The invention relates to the field of electrochemical accumulators.

The subject matter of the invention relates more particularly to a method for estimating a final state of energy of an electrochemical accumulator from a set of quadruplets of values relating to operating points of the electrochemical accumulator including power, temperature, state of energy and remaining energy.

### PRIOR ART

Traditionally, the accumulator state indicator is based on an assessment of the amount of electrical charge stored in the accumulator. The measurement of the intensity of the current drawn from and/or supplied to the accumulator, associated with an integral calculation, can be used to produce the ‘State Of Charge’ (SOC) indicator.

In other words, the following formulae are applied:

Q=∫i.dt+Q0

SOC=100.Q/Qmax

where Q represents the amount of charge stored in the battery at time t in coulombs,

Q0 represents the amount of initial charge stored in the battery in coulombs,

Qmax represents the maximum amount of charge of the battery (full battery) in coulombs, and

SOC represents a state of charge as a percentage.

This common state of charge indicator is not satisfactory insofar as it does not take into account losses in the accumulator, in particular losses due to the internal resistance thereof.

Indeed, the greater the internal resistance of an accumulator, the smaller the amount of energy restored will be. Hence, even if the accumulator stores a very large amount of charge, that actually available will be less. The state of charge value will therefore be distorted, and all the more so the higher the internal resistance of the accumulator.

It has therefore led to a problem of finding another more representative indicator of the actual state of the accumulator.

Document FR2947637 discloses a method for characterizing the state of energy of an accumulator.

The aim of this method is to determine some characteristic points of the behaviour of the accumulator that define a set of values for SOE (state of energy in Wh), P (useful power drawn in W) and En (remaining energy in Wh), which can be represented by mapping in a three-dimensional space as illustrated in FIG. 1.

The state of energy is relative to the available energy at a reference power. This reference power may be that for which the available energy is maximum. The State Of Energy (SOE) then varies from 0 to 1, or from 0 to 100%. For example, for an accumulator whereof the reference energy, at the reference power, is 10 Wh, and taking an experimental point SOE=50%, P=20 W, En=3 Wh, this means that if the accumulator is actually used at the power of 20 W, it can deliver the remaining energy of 3 Wh (and not 5 Wh).

The SOE values of FIG. 1 enabling such reasoning can be determined from a standard accumulator, or a set of accumulators forming a battery, and are therefore standardized in the laboratory in a controlled environment with regard to power and remaining energy in the accumulator.

This patent application gives rise to a problem in using these data, in particular in the context of an onboard application in real time where computing resources are limited.

### SUBJECT MATTER OF THE INVENTION

The purpose of the present invention is to provide a solution that overcomes the drawbacks listed above and that enables a quick resolution of the state of energy.

For addressing this problem, the method for estimating a final state of energy SOEf of an electrochemical accumulator from a set of quadruplets of values relating to operating points of the electrochemical accumulator including power, temperature, state of energy and remaining energy, may include:
a phase of measuring a temperature Tₘ, and a power Pₘ, representative of the current operation of the accumulator,
a phase of determining an initial state of energy SOE[0],
a phase of evaluating an initial remaining energy Eni based on the initial state of energy SOE[0] and the measurements of power Pₘ and temperature Tₘ, and implementing a step of interpolation, in particular linear interpolation, and using at least some quadruplets from the set of quadruplets,
a phase of determining a final remaining energy Enf, a function of the initial remaining energy Eni and an amount of energy drawn from or supplied to the accumulator,
a phase of determining the final state of energy SOEf as a function of the measured power Pₘ, the measured temperature Tₘ and the final remaining energy Enf, implementing a step of interpolation, in particular linear interpolation.

According to one implementation, the phase of evaluating the initial remaining energy Eni may comprise the following steps:
determining a first intermediate remaining energy En_{T1} associated with a temperature T1 higher than the measured temperature Tₘ, and known from the set of quadruplets,
determining a second intermediate remaining energy En_{T2} associated with a temperature T2 lower than the measured temperature Tₘ, and known from the set of quadruplets,
defining the initial remaining energy Eni by linear interpolation between the first and second intermediate remaining energies.

Advantageously, each of the first and second intermediate remaining energies En_{T1}, En_{T2} is determined in the following way:
at the associated temperature, selecting three intermediate points, the coordinates of which include state of energy, power and remaining energy derived from the set of quadruplets, these three intermediate points being the closest to a current intermediate operating point of the accumulator, the current intermediate operating point of the accumulator being a function of the first state of energy SOE[0] and of the measured power Pm,
defining a Cartesian plane equation passing through three selected intermediate operating points,
determining the intermediate remaining energy En_{Tj} as a function of the coefficients of the plane equation, the measured power Pₘ and the initial state of energy SOE[0].

The closest points can be determined by distance calculation using the 2-norm.

According to one implementation, the Cartesian plane equation being written in the form Ax+By+Cz+D=0 with A, B, C and D being determined according to the coordinates of the three selected intermediate operating points, the associated intermediate remaining energy En_{Tj} is calculated according to the formula

$${En}_{Tj} = \frac{- ( A \times SOE [ 0 ] + B \times Pm + D )}{C} .$$

Advantageously, the initial remaining energy Eni is obtained by linear interpolation in accordance with the formula

$$Eni = \frac{( {En}_{T 2} - {En}_{T 1} ) \times ( Tm - T 1 )}{( T 2 - T 1 )} + {En}_{T 1} .$$

According to one implementation, the phase of determining the final state of energy SOEf may include the following steps:
determining a first intermediate state of energy SOE_{1-T1} associated with a temperature T1, higher than the measured temperature Tₘ and known from the set of quadruplets,
determining a second intermediate state of energy SOE_{2-T2} associated with a temperature T2, lower than the measured temperature Tm and known from the set of quadruplets,
defining the final state of energy SOEf by linear interpolation between the first and second intermediate states of energy SOE_{1-T1}, SOE_{2-T2}.

Advantageously, the determination of the first and second intermediate states of energy SOE_{1-T1}, SOE_{2-T2} implements the Cartesian plane equations respectively associated with the first intermediate remaining energy En_{T1} and the second intermediate remaining energy En_{T2}.

Preferably, each intermediate state of energy is determined in the following way:
determining from the associated Cartesian plane, by setting the power to the value of the measured power Pₘ, a plurality of pairs including a state of energy associated with a remaining energy,
selecting from the plurality of pairs the one whereof the remaining energy value is closest to the final remaining energy Enf, so that the corresponding state of energy value is treated as the intermediate state of energy SOE_{j-Tj} sought.

Advantageously, the plurality of pairs is determined over a state of energy range at the level of the initial state of energy SOE[0]. The initial state of energy SOE[0] may be included in the range, or constitute a boundary of the range. Advantageously, the accumulator being in charge phase, the initial state of energy SOE[0] constitutes the lower boundary of the range, or, the accumulator being in discharge phase, the initial state of energy SOE[0] constitutes the upper boundary of the range.

According to one implementation, the final state of energy SOEf is calculated by linear interpolation using the following equation

$$SOEf = \frac{( {SOE}_{2 - T 2} - {SOE}_{1 - T 1} ) \times ( {T}_{m} - T 1 )}{( T 2 - T 1 )} + {SOE}_{1 - T 1} .$$

Advantageously, the method is iterative, and at the end of an iteration the value of the initial state of energy SOE[0] is replaced by that of the final state of energy SOEf.

According to one implementation, the final remaining energy Enf is calculated using the formula Enf=Eni+P.dt where P.dt represents the amount of energy, and is associated with a positive value of power supplied to the accumulator during a determined period in the course of a charge phase, or with a negative value of power output by the accumulator during a determined period in the course of a discharge phase, the determined period corresponding to the iteration interval, in particular between 10 ms and 10 s, or even equal to 1 s.

Preferably, if the accumulator is in charge phase, a correction factor is used to weight the amount of energy.

The invention also relates to a device for determining a state of energy of an accumulator including hardware and software means for implementing the method of estimation as described.

The invention also relates to a computer-readable data recording medium, whereon a computer program is recorded including computer program code means executable by the software means of the device as described for implementing the method of estimation as described.

The invention also relates to a computer program including a computer program code means executable by the software means of the device as described for implementing the method of estimation as described, in particular when the program is executed by a computer.

### SUMMARY DESCRIPTION OF THE DRAWINGS

Other advantages and features will become more apparent from the following description of particular embodiments of the invention given as non-restrictive examples and represented in the accompanying drawings, in which:

FIG. 1 represents the distribution of operating points of an accumulator as a function of the remaining energy, power and state of energy,

FIG. 2 represents an improvement of FIG. 1 in that the operating temperature of the accumulator is also taken into account,

FIG. 3 illustrates the main phases of the method for determining the state of energy,

FIG. 4 illustrates a detail of a phase in FIG. 3,

FIG. 5 illustrates a detail of a step in FIG. 4,

FIG. 6 illustrates a detail of a phase in FIG. 3,

FIG. 7 illustrates a detail of a step in FIG. 6,

FIGS. 8 and 9 illustrate a test protocol for validating the effectiveness of the method for determining the state of energy.

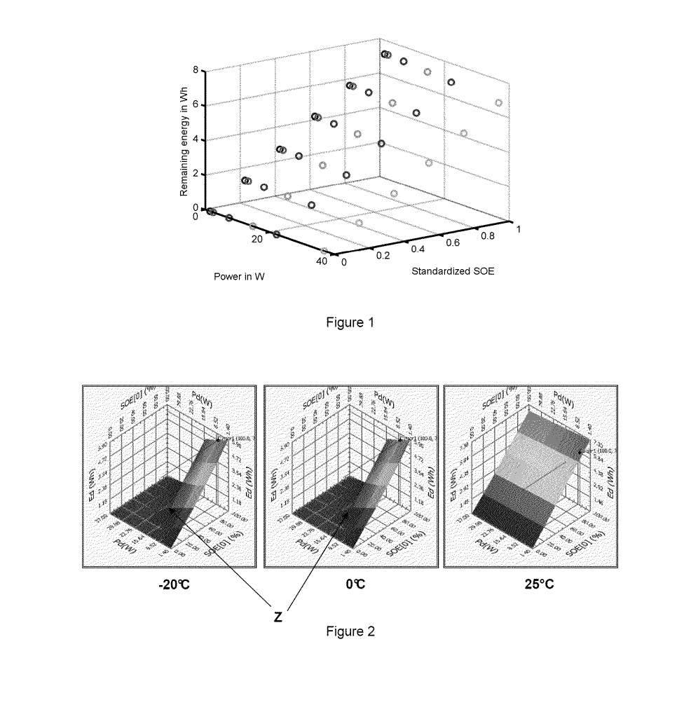

### DESCRIPTION OF PREFERRED EMBODIMENTS OF THE INVENTION

As part of an onboard application, management of the resources for determining a state of energy is a parameter not to be neglected. For this, it has been proposed to start from a set of values relating to operating points of an electrochemical accumulator. Each point includes a power P, a state of energy SOE, a remaining energy En, and a temperature T. The temperature has been included as it affects the behaviour of the internal resistance of the electrochemical accumulator.

In other words, the set may be representative of quadruplets, occurring, for example, in the form of a table En=f(SOE, P, T). By table is meant, for example, a function for giving an output value, advantageously unique, of remaining energy En when the input values of SOE, P and T stored in the table are known.

These data may be represented in the form of mappings as illustrated in FIG. 2. In FIG. 2, three-dimensional spaces are shown, each given by the remaining energy in Wh, the power in W and the state of energy SOE as a %. Three spaces are represented from left to right, and are respectively associated with a temperature of −20° C., 0° C. and 25° C. Thus, for each temperature value, there is a set of values of power, state of energy and remaining energy. In FIG. 2, for each temperature the operating points are modelled on an array shown in different shades of grey, and delimiting a virtual surface associated with a temperature. Each known mesh of each array corresponds to an operating point determined by experimental measurement function of the quadruplet (SOE, remaining energy, power, temperature). The number of operating points is quite low, since even if the experiments are automated, they are lengthy.

Before detailing the steps of a method of implementation of the invention, it is first necessary to supply some definitions.

A ‘State Of Energy’ SOE, is defined as the ratio between the available energy E_{d/PN}, on the assumption of a discharge of energy under the nominal conditions of the accumulator, and the nominal energy E_{Nom}, therefore defined by the formula SOE=E_{d/PN}/E_{Nom}. This value of SOE is between 0 and 1, the value equal to 1 corresponding to a state of energy of the fully charged accumulator, and the value equal to 0 to a fully discharged state. This value may also be expressed as a percentage.

The power P is within a power use range recommended by the manufacturer of the accumulator, either supplied directly by this manufacturer, or deduced, for example, from a current range supplied by this manufacturer, through multiplication by a supplied nominal voltage.

This power is a function of the state of use of the accumulator, namely charging or discharging. In the case of discharging, it means that the power P is drawn from the accumulator, and in the case of charging, it means that the power P is supplied to the accumulator.

The charged and discharged states are determined according to the technology of the accumulator. They can be obtained from the accumulator manufacturer's recommendations, and generally based on threshold voltages.

The remaining energy En is the useful energy of the accumulator, it is expressed in Wh, and takes into account the internal energy actually stored in the accumulator, and the energy lost by Joule effect in the internal resistance of the accumulator. Thus:

En=Ei−Ep

With

Ep=∫r.I².dt representing the energy lost by Joule effect in the internal resistance of the accumulator, and

Ei=Q.U representing the internal energy stored in the accumulator.

The set of quadruplets may be generated as described in the French patent application published under number FR2947637 in addition taking into account the temperature (FIG. 2). In fact, the state of energy and remaining energy values may vary according to the temperature representative of the operation of the accumulator, which is why it is advantageous to take the latter into account. The person skilled in the art will therefore be able to generate such a set, e.g. by experimentation.

Thus, a method has been developed for estimating a final state of energy SOEf of an electrochemical accumulator from a set of quadruplets of values relating to operating points of the electrochemical accumulator including power P, temperature T, state of energy SOE and remaining energy En. This method is advantageously iterative, and at the end of an iteration, the value of the initial state of energy SOE[0] is replaced by that of the final state of energy SOEf, e.g. by modifying the corresponding value in a memory.

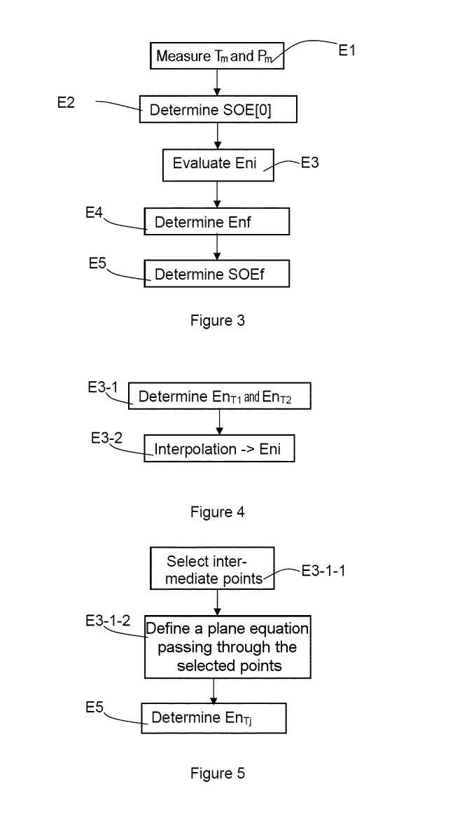

In FIG. 3, the method comprises a phase E1 in which a temperature Tₘ and a power Pₘ are measured. Said temperature Tₘ and power Pₘ are representative of the current operation of the accumulator. ‘Current’ refers to the operating state of the accumulator in particular during iteration. Power and temperature representative of the accumulator refer to the power at which energy is drawn from or supplied to the accumulator, and the operating temperature of the accumulator. With regard to the data present in the quadruplets, the stored power values P are advantageously all positive. Hence, if a negative power Pm is measured, it is known that the accumulator is discharging, and if a positive power Pm is measured, it is known that the accumulator is charging. In the case where the quadruplets contain only positive values of power, the absolute value of the measured power Pm will be taken for extracting data from the quadruplets, and the sign of the power is used for determining whether charging, or discharging, is involved. The temperature Tm is advantageously measured as close as possible to the accumulator, generally at the surface thereof. In the case where the accumulator forms a battery of elementary accumulators, it is possible to use a plurality of temperature sensors and to use an average of the temperatures measured by these sensors as the value Tm.

In a phase E2, an initial state of energy SOE[0] is determined. This determination may be performed by reading the corresponding value in the memory referred to above. Typically, since the method is iterative, in the iteration in progress, the initial state of energy SOE[0] in fact corresponds to the final state of energy SOEf of the preceding iteration. In the very first initialization state, the accumulator may be charged to its maximum, and when charging stops, the value in the memory is representative of 100%. Or conversely, the accumulator may be completely discharged, and the value stored in memory at the time of initialization may be representative of 0%.

Although in FIG. 3, phase E2 is represented as consecutive to phase E1, it may very well be performed before, concomitantly, or after phase E2.

Once the values of measured power Pₘ, measured temperature Tₘ and initial state of energy SOE[0] are known, a phase of evaluating E3 an initial remaining energy Eni is performed based on the initial state of energy SOE[0] and the measurements of power Pₘ and temperature Tₘ. This evaluation phase implements a step of interpolation, in particular of linear interpolation, and uses at least some quadruplets from the set of quadruplets.

FIG. 4 illustrates a particular, and non-restrictive, embodiment of phase E3. Initially in E3-1, a first intermediate remaining energy En_{T1} is determined associated with a temperature T1 higher than the measured temperature Tₘ. This temperature T1 is known from the set of quadruplets. A second intermediate remaining energy En_{T2} is also determined associated with a temperature T2 lower than the measured temperature Tₘ. This temperature T2 is known from the set of quadruplets. Once these two intermediate values are known, in E3-2 the initial remaining energy Eni is defined by linear interpolation between the first and second intermediate remaining energies.

For selecting T1 and T2, in the set of quadruplets the temperature value advantageously directly above Tₘ is taken for T1, and the temperature value advantageously directly below Tₘ is taken for T2. If Tm=T1, then Eni equals En_{T1}, and if Tm=T2 then Eni equals En_{T2}.

Advantageously, the linear interpolation from En_{T1} and En_{T2}, gives the initial remaining energy Eni in accordance with the formula

$$Eni = \frac{( {En}_{T 2} - {En}_{T 1} ) \times ( Tm - T 1 )}{( T 2 - T 1 )} + {En}_{T 1} .$$

FIG. 5 illustrates a particular implementation of step E3-1 during which it is sought to determine En_{T1} and En_{T2}. Typically, at the associated temperature, i.e. T1 for determining En_{T1}, or T2 for determining En_{T2}, three intermediate points are selected E3-1-1 whereof the coordinates include state of energy, power and remaining energy derived from the set of quadruplets, these three intermediate points being the closest to a current intermediate operating point of the accumulator. The current intermediate operating point of the accumulator is a function of the first state of energy SOE[0] and of the measured power Pₘ. Thus, the closest intermediate points can be determined from a set of state of energy and power pairs selected from the set of quadruplets at the given temperature (where applicable according to T1 or T2). The set of pairs can be represented in a plane giving the state of energy as a function of power. Once the three pairs have been selected, it is possible to extract, for each pair the value of the associated remaining energy, as a function of the temperature T1, or where applicable the temperature T2, contained in the set of quadruplets. Thus the three intermediate operating points are formed. Once the three points are known, a Cartesian plane equation passing through the three selected intermediate operating points is defined E3-1-2. In other words, for the temperature T1 a Cartesian plane will therefore be determined from intermediate operating points determined from a subset of points derived from the set of quadruplets, and all associated with the same temperature T1, this Cartesian plane, in particular via the coefficients thereof, then being used for determining En_{T1}. Similarly, for the temperature T2 a Cartesian plane will be determined from intermediate operating points determined from a subset of points derived from the set of quadruplets, and all associated with the same temperature T2, this Cartesian plane, in particular via the coefficients thereof, then being used for determining En_{T2}.

The intermediate remaining energy (En_{Tj} with j=1 or 2, i.e. En_{T1}, or where applicable En_{T2}) is determined E3-1-3 from the coefficients of the equation of the associated Cartesian plane (that associated with the temperature T1 for En_{T1}, or that associated with the temperature T2 for En_{T2}), Pₘ and SOE[0].

Advantageously, the closest points are determined by distance calculation using the 2-norm, typically applied to vectors defined by two points each associated with a power and a state of energy. In fact, the 2-norm is used to calculate the ‘norm’ of a vector defined by the known operating point and one of the intermediate operating points. The distance can be calculated by taking the pair representative of the current intermediate operating point (SOE[0], Pm) and performing, for each pair of the set of pairs defined above, a calculation of distance d in the following way: d={square root over ((DeltaSOE²+DeltaP²)} taking DeltaSOE a variation value separating SOE[0] from the value of SOEₜₑₛₜ of the tested pair derived from the set of quadruplets at the given temperature T1 or T2 (e.g. SOE[0] minus SOEₜₑₛₜ) and DeltaP a variation value separating Pₘ from the value Pₜₑₛₜ of the pair derived from the set of quadruplets at the given temperature T1 or T2 (e.g. Pₘ minus Pₜₑₛₜ). These distance calculations can be simplified by prefiltering through sampling the mappings.

In fact, the Cartesian plane equation being written in the form Ax+By+Cz+D=0 (eq1) with A, B, C and D being determined according to the coordinates of the three selected intermediate operating points, at the associated T1 or T2, the associated intermediate remaining energy En_{Tj} is calculated according to the formula

$${En}_{Tj} = \frac{- ( A \times SOE [ 0 ] + B \times Pm + D )}{C} ,$$

with j equal to 1 or 2 as applicable.

Thus, with the three selected intermediate operating points M(x1, y1, z1), N(x2, y2, z2) and O(x3, y3, z3) with x1, x2, x3 the respective state of energy values, y1, y2, y3 the respective power values, and z1, z2, z3 the respective remaining energy values of these points, we have:

A=(y₂−y₁)×(z₃−z₁)−(y₃−y₁)×(z₂−z₁)

B=−[(x₂−x₁)×(z₃−z₁)−(x₃−x₁)×(z₂−z₁)]

C=(x₂−x₁)×(y₃−y₁)−(x₃−x₁)×(y₂−y₁)

D=−(Ax₁+By₁+Cz₁)

Once the initial remaining energy Eni is known, a phase of determining E4 (FIG. 3) a final remaining energy Enf is performed as a function of the initial remaining energy Eni and an amount of energy drawn from or supplied to the accumulator. In fact, the amount of energy will be different if the accumulator is in a charge phase (energy supplied to the accumulator) or discharge phase (energy drawn from the accumulator). In other words, the final remaining energy Enf can be calculated according to the formula Enf=Eni+P.dt where P.dt represents the amount of energy, and is associated with a positive value of power supplied to the accumulator during a determined period in the course of a charge phase, or with a negative value of power output by/drawn from the accumulator during a determined period in the course of a discharge phase. Advantageously, the determined period corresponds to the iteration interval. The iteration interval is advantageously between 10 ms and 10 s, in particular equal to 1 s. In fact, everything will be linked to the actual flow of information within an associated computer and the refreshing of the indicators.

In the case where the accumulator is in charge phase, a correction factor is used, preferably, to weight the amount of energy. The correction factor may be determined from a table made during a calibration phase and giving a correction value according to the temperature and the state of charge. The value to be used for weighting may be determined during an interpolation by Cartesian plane from the table so as to find a value associated with Tm and SOE[0].

To conclude, consecutively to phase E4, the method comprises a phase of determining E5 the final state of energy SOEf as a function of the measured power Pₘ, the measured temperature Tₘ and the final remaining energy Enf, implementing a step of interpolation, in particular linear interpolation and advantageously using at least some quadruplets from the set of quadruplets.

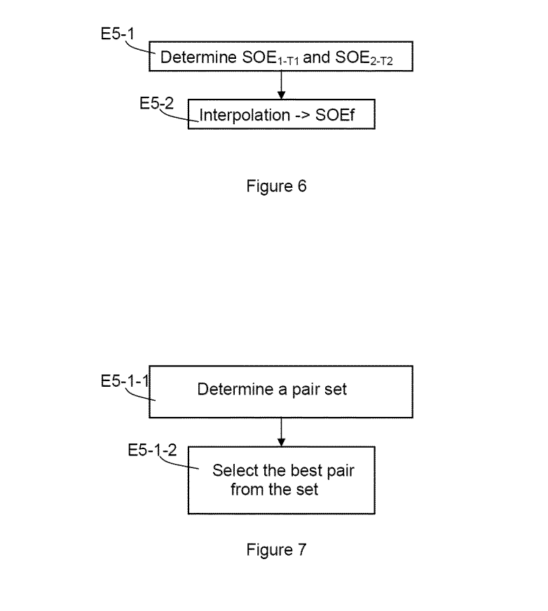

FIG. 6 illustrates a particular embodiment of phase E5 in more detail and non-restrictively. This phase E5 is divided into steps E5-1 and E5-2.

In step E5-1 firstly a first intermediate state of energy SOE_{1-T1} associated with a temperature T1, is determined, higher than the measured temperature Tₘ and known from the set of quadruplets, and secondly a second intermediate state of energy SOE_{2-T2} is determined, associated with a temperature T2, lower than the measured temperature Tₘ and known from the set of quadruplets. In fact, the values of T1 and T2 are advantageously identical to those determined earlier for calculating the intermediate remaining energies. In step E5-2, the final state of energy SOEf is defined by linear interpolation between the first and second intermediate states of energy SOE_{1-T1}, SOE_{2-T2}.

This linear interpolation is advantageously implemented by applying the equation:

$$SOEf = \frac{( {SOE}_{2 - T 2} - {SOE}_{1 - T 1} ) \times ( {T}_{m} - T 1 )}{( T 2 - T 1 )} + {SOE}_{1 - T 1} .$$

According to a particular implementation, the determination of the first and second intermediate states of energy SOE_{1-T1}, SOE_{2-T2} implements the Cartesian plane equations respectively associated with the first intermediate remaining energy En_{T1} and the second intermediate remaining energy En_{T2} (here this refers to the equations eq1 defined above for temperatures T1 and T2). Typically, for determining SOE-_{1-T1} the Cartesian plane equation that helped to determine En_{T1} is used, and for determining SOE_{2-T2} the Cartesian plane equation that helped to determine En_{T2} is used.

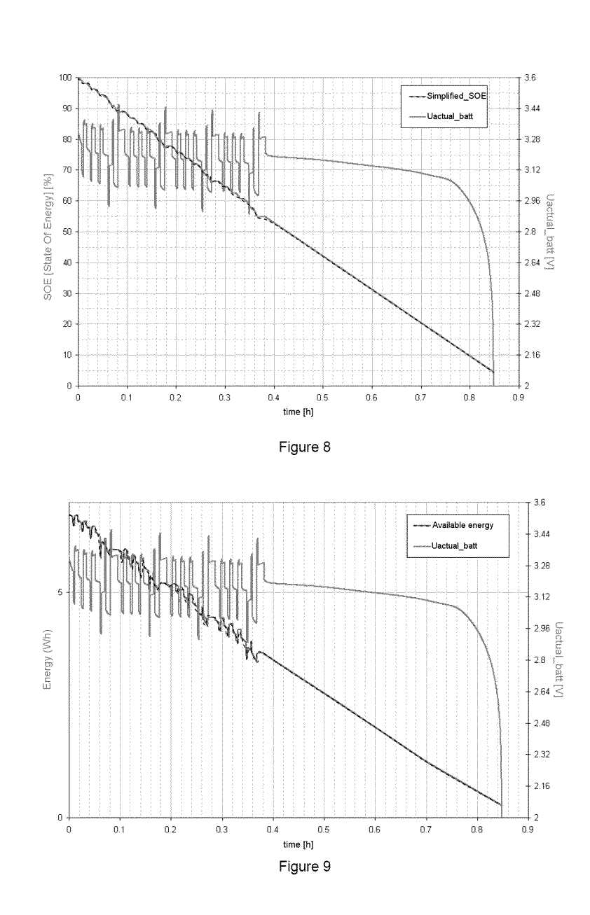

In this case, each intermediate state of energy may be determined according to the refinement of step E5-1 illustrated in FIG. 7. Initially in E5-1-1, a plurality of pairs including a state of energy associated with a remaining energy are determined from the associated Cartesian plane, by setting the power to the value of the measured power Pₘ. These pairs may be determined from the equation of the associated Cartesian plane with an interval resolution separating two predetermined state of energy values. Then, in E5-1-2 from the plurality of pairs the one whereof the remaining energy value is closest to the final remaining energy Enf is selected, so that the corresponding state of energy value is treated as the intermediate state of energy SOE_{j-Tj} sought (with j=1 or 2). In fact, by considering the equation of the plane all the possible pairs could be tested, however, for reasons of execution time and computational resources, it is preferable to determine only certain pairs.

By conducting tests outside of the onboard application, it was determined that the pair actually selected was always associated with a state of energy quite close to the initial state of energy SOE[0]. Thus, advantageously the plurality of pairs is determined over a state of energy range at the level of the initial state of energy SOE[0]. Typically, the initial state of energy SOE[0] is included in the range, or constitutes a boundary of the range. In fact, if the accumulator is in charge phase, the initial state of energy SOE[0] constitutes the lower boundary of the range. If the accumulator is in discharge phase, the initial state of energy SOE[0] constitutes the upper boundary of the range. Thus, knowing the Cartesian plane equation, SOE[0], and Pₘ, it is easy to test a plurality of state of energy values close to SOE[0] for determining the associated remaining energy value in order to compare it with the final remaining energy.

The definition of this range corresponds, in fact, to delimiting a search window of +/−0.1% from SOE[0]. Typically, 10 interpolation calculations will be performed starting from the value of SOE[0] with an interval of 0.01% if it is known whether the accumulator is in charge or discharge phase. In fact, according to the resources available for performing calculations, the choice of filtering parameters, i.e. the size of the window and the calculation interval, may be dependent on the application and the temporal sampling interval. These calculations are made according to a positive evolution from SOE[0] if the accumulator is charging, or according to a negative evolution if the accumulator is discharging.

A computer-readable data recording medium, whereon a computer program is recorded may include computer program code means of implementing the phases and/or steps of the method for determining the final state of energy SOEf.

A computer program including computer program code means may be adapted to the implementation of the phases and/or steps of the method for determining the state of energy, when the program is executed by a computer.

A device for determining a state of energy of an electrochemical accumulator may comprise: an element for storing the first set; an element for measuring a temperature Tₘ, and a power Pₘ, representative of the current operation of the accumulator; an element for determining an initial state of energy SOE[0], including in particular a memory; an element configured for evaluating an initial remaining energy Eni from the measurements of power Pₘ, temperature Tₘ and initial state of energy SOE[0] implementing a step of interpolation, in particular linear interpolation, and using the set of quadruplets; an element configured for determining a final remaining energy Enf, a function of the initial remaining energy Eni and an amount of energy drawn from or supplied to the accumulator; an element configured for determining the final state of energy SOEf as a function of the measured power Pₘ, the measured temperature Tₘ and the final remaining energy Enf, implementing a step of interpolation, in particular linear interpolation, and advantageously using at least some quadruplets from the set of quadruplets.

Generally speaking, the device may include hardware and/or software means for implementing the steps/phases of the determination method as described (more particularly, the hardware and/or software means may implement the determination method as described).

In particular, the device may comprise for each phase and/or step of the method an element that is dedicated and configured for performing the phase and/or said step.

From what has been said above it is clear that the computer program on the recording medium may include computer program code means executable by the software means of the device as described for implementing the method as described.

Furthermore, it is also clear that the computer program may include a computer program code means executable by the software means of the device as described for implementing the method as described, in particular when the program is executed by a computer.

In order to test the present determination method, a power profile, with charge and discharge phases, has been applied to an accumulator. During the test, the voltage at the accumulator terminals and the accumulator temperature were recorded.

Moreover, the power profile and the operating temperature of the accumulator were injected into a simulation of the calculation algorithm for estimating the state of energy previously described. As part of this simulation use was made of:
experimental mappings (6 values of SOE by 6 values of P by 6 values of T or 288 associated En values, in other words 288 quadruplets),
the method of interpolation by Cartesian planes previously described,
a calculation accuracy of the SOE of 0.01% and a calculation range of 0.1%.

The iterative algorithm corresponds to a time interval dt=1 s.

The results of the simulated state of energy and the voltage actually measured can then be compared. FIG. 8 illustrates the evolution of the voltage Uactual_batt of the accumulator as a function of time (in hours h) and the evolution of the state of energy (SOE as a %) as a function of time (in hours h) during a discharge phase of the accumulator. FIG. 9 illustrates the evolution of the voltage Uactual_batt of the accumulator as a function of time (in hours h) and the evolution of the remaining energy (Wh) as a function of time (in hours h) during a discharge phase of the accumulator. FIGS. 8 and 9 show that, at the end of discharge, the state of energy (SOE) and the available energy are actually close to 0 (<4% for SOE ˜250 mWh for the available remaining energy). This estimate is sufficient in the context of an onboard application whereof the resources are limited.

As previously mentioned, the set of quadruplets may be derived from experimental data. Before being used in the present method, this set may be completed by interpolation. This interpolation may be performed in temperature, in state of energy and in power. Advantageously, the more the functions of the state of energy with respect to power use and temperature are irregular, the greater the number of modelling points there must be. It is conceivable to increase the number of modelling points only at places where irregularities are located. Typically in FIG. 2, the reference Z indicates such an irregularity. Increasing the number of points only at irregularities can be used to reduce the size of the memory containing the mapping to the detriment of simplicity of searching in the memory when the application is executed.

The mappings representing the quadruplets may be generated on computer using scientific calculation software such as matlab, mathcad, octave, scilab, etc., or else simply be derived from experimental points as required.

Thus, the set of quadruplets used in the context of determining the state of energy, derived from experimental data or not, may be stored in a memory which will be used by a computer. In fact, the more values the set of quadruplets comprises, the more accurate the algorithm will be.

The description refers to an electrochemical accumulator. The definition of the accumulator should be broadly interpreted, and is equally aimed at an elementary accumulator or a plurality of elementary accumulators arranged in the form of a battery. The reference accumulator used for the tests comes from the manufacturer A123systems and bears the reference ANR26650M1.

Cartesian planes were used earlier for best approximating the state of energy value. Instead of Cartesian planes it is possible to use a linear interpolation via a 3-hyperplane in a 4-space from the set of quadruplets. However, this implementation is not to be preferred since it is too demanding of computer resources.

According to one embodiment, at the end of iteration SOEf can be compared with SOE[0] so that if the latter two are equal, i.e. the gauge has not moved, the variation in energy is still integrated at the next interval instead of recalculating Eni by inverse interpolation. The integration continues from iteration to iteration until there is a state of energy different from the previous interval. This enables greater accuracy if a low power is output for a long time.

1. Method for estimating a final state of energy SOEf of an electrochemical accumulator from a set of quadruplets of values relating to operating points of the electrochemical accumulator including power (P), temperature (T), state of energy (SOE) and remaining energy (En), said method including:
a phase of measuring a temperature Tₘ, and a power Pₘ, representative of the current operation of the accumulator,
a phase of determining an initial state of energy SOE[0],
a phase of evaluating an initial remaining energy Eni based on the initial state of energy SOE[0] and the measurements of power Pₘ and temperature Tₘ, and implementing a step of interpolation, and using at least some quadruplets from the set of quadruplets,
a phase of determining a final remaining energy Enf, a function of the initial remaining energy Eni and an amount of energy drawn from or supplied to the accumulator,
a phase of determining the final state of energy SOEf as a function of the measured power Pₘ, the measured temperature Tₘ and the final remaining energy Enf, implementing a step of interpolation.

2. Method according to claim 1, wherein the phase of evaluating the initial remaining energy Eni comprises the following steps:
determining a first intermediate remaining energy En_{T1} associated with a temperature T1 higher than the measured temperature Tₘ, and known from the set of quadruplets,
determining a second intermediate remaining energy En_{T2} associated with a temperature T2 lower than the measured temperature Tₘ, and known from the set of quadruplets,
defining the initial remaining energy Eni by linear interpolation between the first and second intermediate remaining energies.

3. Method according to claim 2, wherein each of the first and second intermediate remaining energies En_{T1}, En_{T2} is determined in the following way:
at the associated temperature, selecting three intermediate points, the coordinates of which include state of energy, power and remaining energy derived from the set of quadruplets, these three intermediate points being the closest to a current intermediate operating point of the accumulator, the current intermediate operating point of the accumulator being a function of the first state of energy SOE[0], and of the measured power Pm,
defining a Cartesian plane equation passing through three selected intermediate operating points,
determining the intermediate remaining energy En_{Tj} as a function of the coefficients of the plane equation, the measured power Pm and the initial state of energy SOE[0].

4. Method according to claim 3, wherein the closest points are determined by distance calculation using the 2-norm.

5. Method according to claim 3, wherein, the Cartesian plane equation being written in the form Ax+By+Cz+D=0 with A, B, C and D being determined according to the coordinates of the three selected intermediate operating points, the associated intermediate remaining energy En_{Tj} is calculated according to the formula
$${En}_{Tj} = \frac{- ( A \times SOE [ 0 ] + B \times Pm + D )}{C} .$$

6. Method according to claim 2, wherein the initial remaining energy Eni is obtained by linear interpolation in accordance with the formula
$$Eni = \frac{( {En}_{T 2} - {En}_{T 1} ) \times ( Tm - T 1 )}{( T 2 - T 1 )} + {En}_{T 1} .$$

7. Method according to claim 1, wherein the phase of determining the final state of energy SOEf includes the following steps:
determining a first intermediate state of energy SOE_{1-T1} associated with a temperature T1, higher than the measured temperature Tₘ and known from the set of quadruplets,
determining a second intermediate state of energy SOE_{2-T2} associated with a temperature T2, lower than the measured temperature Tm and known from the set of quadruplets,
defining the final state of energy SOEf by linear interpolation between the first and second intermediate states of energy SOE_{1-T1}, SOE_{2-T2}.

8. Method according to claim 3,
wherein the phase of determining the final state of energy SOEf includes the following steps:
determining a first intermediate state of energy SOE_{1-T1} associated with a temperature T1, higher than the measured temperature Tₘ and known from the set of quadruplets,
determining a second intermediate state of energy SOE_{2-T2} associated with a temperature T2, lower than the measured temperature Tm and known from the set of quadruplets,
defining the final state of energy SOEf by linear interpolation between the first and second intermediate states of energy SOE_{1-T1}, SOE_{2-T2},
wherein the determination of the first and second intermediate states of energy SOE_{1-T1}, SOE_{2-T2} implements the Cartesian plane equations respectively associated with the first intermediate remaining energy En_{T1} and the second intermediate remaining energy En_{T2}.

9. Method according to claim 8, wherein each intermediate state of energy is determined in the following way:
determining from the associated Cartesian plane, by setting the power to the value of the measured power Pₘ, a plurality of pairs including a state of energy associated with a remaining energy,
selecting from the plurality of pairs the one whereof the remaining energy value is closest to the final remaining energy Enf, so that the corresponding state of energy value is treated as the intermediate state of energy SOE_{j-Tj} sought.

10. Method according to claim 9, wherein the plurality of pairs is determined over a state of energy range at the level of the initial state of energy SOE[0].

11. Method according to claim 10, wherein the initial state of energy SOE[0 ] is included in the range, or constitutes a boundary of the range.

12. Method according to claim 11, wherein, the accumulator being in charge phase, the initial state of energy SOE[0] constitutes the lower boundary of the range, wherein, the accumulator being in discharge phase, the initial state of energy SOE[0] constitutes the upper boundary of the range.

13. Method according to claim 7, wherein the final state of energy SOEf is calculated by linear interpolation using the following equation
$$SOEf = \frac{( {SOE}_{2 - T 2} - {SOE}_{1 - T 1} ) \times ( {T}_{m} - T 1 )}{( T 2 - T 1 )} + {SOE}_{1 - T 1} .$$

14. Method according to any one of claim 1, wherein the method is iterative, and at the end of an iteration the value of the initial state of energy SOE[0] is replaced by that of the final state of energy SOEf.

15. Method according to claim 14, wherein the final remaining energy Enf is calculated using the formula Enf=Eni+P.dt where P.dt represents the amount of energy, and is associated with a positive value of power supplied to the accumulator during a determined period in the course of a charge phase, or with a negative value of power output by the accumulator during a determined period in the course of a discharge phase, the determined period corresponding to the iteration interval.

16. Method according to claim 1, wherein, the accumulator being in charge phase, a correction factor is used to weight the amount of energy.

17. Device for determining a state of energy of an accumulator, including hardware and software means for implementing the method according to claim 1.

18. Computer-readable data recording medium, whereon a computer program is recorded including computer program code means executable by software means of a device for determining a state of energy of an accumulator for implementing the method according to claim 1.

19. Computer program including a computer program code means executable by the software means of a device for determining a state of energy of an accumulator for implementing the method according to claim 1.

20. Method according to claim 1, wherein the step of interpolation is a step of linear interpolation.
